(19) United States
(12) Patent Application Publication
(10) Pub. No.: US 2020/0286809 A1
(43) Pub. Date: Sep. 10, 2020

(54) CARBON-PAD THERMAL-INTERFACE MATERIALS IN MULTI-DIE PACKAGES

(71) Applicant: Intel Corporation, Santa Clara, CA (US)

(72) Inventors: Shushan Gong, Phoenix, AZ (US); James C. Matayabas, JR., Chandler, AZ (US)

(21) Appl. No.: 16/293,163

(22) Filed: Mar. 5, 2019

(51) Int. Cl. H01L 23/373; H01L 25/11; H01L 23/367; H01L 23/538; F28F 21/02

(52) U.S. Cl. CPC H01L 23/3737; H01L 25/115; F28F 21/02; H01L 23/5381; H01L 23/5386; H01L 23/3672

(57) ABSTRACT

Multi-die semiconductor device packages include a solder thermal interface material for a processor device, and a carbon-pad thermal interface material for a high-bandwidth memory device. Disparate dice are packaged against a heat sink on the device backsides, and on a semiconductor package substrate on the device active surfaces and metallizations.

### FIELD

This disclosure relates heat management in pluralistic-packaging enabling solutions.

### BACKGROUND

Semiconductive device miniaturization during packaging includes challenges to manage heat among disparate semiconductive devices that have been packaged.

### BRIEF DESCRIPTION OF THE DRAWINGS

Disclosed embodiments are illustrated by way of example, and not by way of limitation, in the figures of the accompanying drawings where like reference numerals may refer to similar elements, in which:

FIG. 1 is a cross-section elevation of a semiconductor device package according to an embodiment;

FIG. 2 is a top plan of the semiconductor device package depicted in FIG. 1, where FIG. 1 can be viewed in cross section according to several embodiments;

FIG. 3 is a top plan a semiconductor device package according to several embodiments;

FIG. 4 is a cross-section representation of a carbon-pad thermal interface material according to an embodiment;

FIG. 5 is a process flow diagram according to several embodiments; and

FIG. 6 is included to show an example of a higher-level device application for the disclosed embodiments.

### DETAILED DESCRIPTION

Multi-chip packages with high bandwidth memory (HBM) capabilities are packaged with data-voracious processors such as central processing units (CPUs) and graphics processing units (GPUs). Different thermal-interface materials (TIMs) are applied to the various semiconductive devices at the die backsides, to provide enabling heat-management solutions for the multichip package embodiments.

Carbon-pad TIMs are used under compressive load to extract excess heat from HBM devices. Central devices use metal alloy TIMs such as solder TIMs (sTIMs). During reflow seating of a heat sink on an sTIM, solder flux may spread into the space required by the adjacent carbon-pad TIM. Such flux spread does not cause permanent heat-transfer issues for the carbon-pad TIM. A “carbon-pad TIM” may be understood to be a carbon material that is imbued with a flexible material such as a polymer matrix. In an embodiment, the carbon-pad TIM is a pad with generally vertically oriented graphite and carbon nanotubes, which are imbued with a fluoropolymer rubber matrix.

In an embodiment, a CPU is packaged with an HBM semiconductive device (HBM chip), where the CPU has an sTIM and the HBM chip has a carbon-pad TIM. Disparate die-backside heights, if present, of the CPU and the HBM chip, are equilibrated when contacted with a heat sink, such as an integrated heat spreader (IHS) that has a substantially planar die-contact surface by integrated-device packaging standards. While sTIM technology is used for a processor, carbon-pad TIM technology is used for the HBM chip.

In an embodiment, the CPU requires a thicker sTIM for an enabling heat-transfer solution, than the HBM chip, and the HBM chip uses a carbon-pad TIM, that provides a thermal resistance of less than 0.2° C. cm²/Watt at a bond-line thickness (BLT) in a range from 250-450 micrometer (μm).

In an embodiment, a GPU is packaged with an HBM chip, where the GPU has an sTIM and the HBM chip has a carbon-pad TIM. Disparate die-backside heights, if present, of the GPU and the HBM chip, are equilibrated when contacted with a heat sink, such as an IHS that has a substantially planar die-contact surface by integrated-device packaging standards. In an embodiment, the GPU requires a thicker sTIM for an enabling heat-transfer solution, than the HBM chip, and the HBM chip uses a carbon-pad TIM, that provides a thermal resistance of less than 0.2° C. cm²/Watt at a BLT in a range from 250-450 μm.

In an embodiment, an HBM die operates with about 1024 data links at a rate of about 500 MHz. In an embodiment, one HBM die operates in connection with a GPU, and one HBM die operates with a CPU. In an embodiment, the HBM die operates at 512 GB/s.

In an embodiment, a carbon-pad TIM is compressed by the heat spreader, in a compressive-force range from about 30 pounds force per square inch (psi) to about 90 psi, and the thermal resistance is in a range from about 0.3 to 0.1° C. cm²/Watt.

Several semiconductive devices are disclosed. A “semiconductive device” may be referred to as chip where after semiconductor processing at front-end-of line (FEOL) techniques, completed active and passive devices on silicon are completed, back-end-of line (BEOL) processing achieves metallization that contacts the active and passive devices, followed by die singulation. Die singulation results in semiconductive devices that are also referred to as chips. The device may also be referred to as an integrated circuit chip.

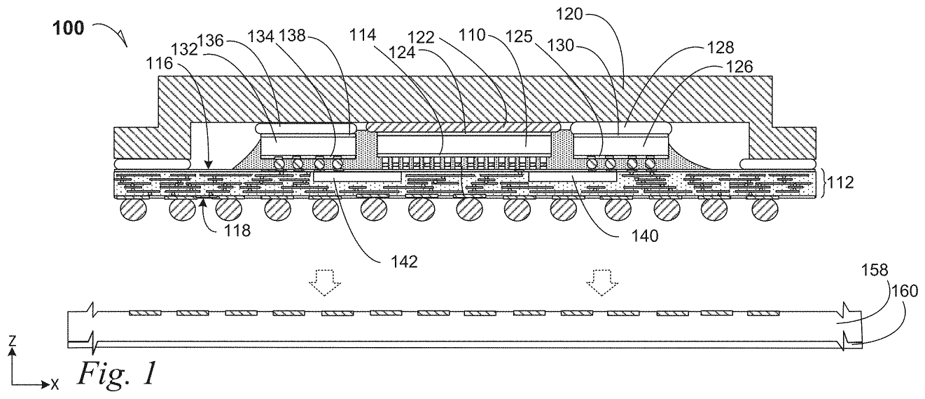

FIG. 1 is a cross-section elevation of a semiconductor device package 100 according to an embodiment. A processor semiconductive device (processor die) 110 is mounted on a semiconductor package substrate 112, where the processor die 110 includes an active surface and metallization 114 that faces the semiconductor package substrate 112. The semiconductor package substrate 112 includes a die side 116 that is opposite a land side 118.

In an embodiment, the processor die 110 is a central-processing unit semiconductive device (CPU die) 110. In an embodiment, the processor die 110 is a graphics-processing unit semiconductive device (GPU die) 110. In an embodiment, the processor die 110 is thermally bonded to a heat sink 120, through a solder-containing thermal-interface material (sTIM) 122. Generally, the TIM 122 is a metal or metal alloy TIM 122.

In an embodiment, a die-backside metallization (DBM) 124 interfaces between bulk semiconductive material of the processor die 110 and the sTIM 122. In an embodiment, no DBM 124 is present, and the bulk semiconductive material of the processor die 110 interfaces with the sTIM 122.

In an embodiment, where the processor die 110 is a first die, a subsequent semiconductive device 126 is mounted near the first die 110. In an embodiment, the subsequent semiconductive device 126 is a high-bandwidth memory semiconductive device (HBM die) 126, that is mounted on the semiconductor package substrate 112. The HBM die 126 includes an active surface and metallization 125 that faces the semiconductor package substrate 112 on the die side 116. In an embodiment, the HBM die 126 is thermally bonded to the heat sink 120, through a carbon-pad TIM 128. In an embodiment, a DBM 130 interfaces between bulk semiconductive material of the HBM die 126 and the carbon-pad TIM 128. In an embodiment, no DBM 130 is present, and the bulk semiconductive material of the HBM die 126 at its backside, interfaces with the carbon-pad TIM 128.

In an embodiment, the carbon-pad TIM 128 is an assembly of graphite planes imbued with a fluoropolymer rubber material. In an embodiment, the graphite planes are principally oriented in the Z-direction, to assist in making graphite-plane conduits between the backside of the HBM die 126 and the heat sink 120.

In an embodiment, the carbon-pad TIM 128 is an assembly of carbon nanotubes imbued with a fluoropolymer rubber material. In an embodiment, the carbon nanotubes are principally oriented in the Z-direction, to assist in making substantially continuous graphite-tube conduits between the backside of the HBM die 126 and the heat sink 120.

In an embodiment, carbon fillers are imbued with a flexible medium such as a polymer. In an embodiment, carbon structures with an aspect ratio (major length to minor width) in a range from 1:1 to 1:100 are imbued with a flexible medium such as a polymer.

The following table is an approximation of thermal resistance as a function of applied pressure in pounds force per square inch for a carbon-nanotube containing carbon-pad TIM that is imbued with a fluoropolymer rubber matrix. In an embodiment, the flexible material is interstitially found among the carbon materials.

| Pressure | R, ° C. cm2/W |
|---|---|
| 10 | 0.34 |
| 20 | 0.225 |
| 30 | 0.17 |
| 40 | 0.14 |
| 50 | 0.12 |
| 60 | 0.10 |
| 70 | 0.08 |
| 80 | 0.075 |

In an embodiment, where the processor die 110 is a first semiconductive device the subsequent semiconductive device 126 is present, a third semiconductive device 132 is mounted near the first die 110. In an embodiment, the third semiconductive device 132 is an HBM die 132, with an active surface and metallization 134 facing the semiconductor package substrate 112 on the die side 116. In an embodiment, the third die 132 is thermally bonded to the heat sink 120, through a carbon-pad TIM 136. In an embodiment, the carbon-pad TIM 136 is of the same construction as the carbon-pad TIM 128. In an embodiment, the carbon-pad TIM 136 is of a different construction as the carbon-pad TIM 128, such that enabling thermal solutions for the respective dice 126 and 132 have accommodating different heat-transfer qualities. In an embodiment, the TIM 136 is a metallic-based TIM 136 of the same composition as the sTIM 122. In an embodiment, the TIM 136 is a metallic-based TIM 136 of a composition compared to the sTIM 122, such that enabling thermal solutions for the respective dice 110 and 132 have accommodating but different heat-transfer qualities. In an embodiment, the third TIM 136 is an elastomer-pad TIM. The elastomer-pad TIM may include a silicon material of a thermally conductive rubber.

In an embodiment, the third TIM 136 is a vertically oriented graphitic carbon TIM. In an embodiment the third TIM 136 is a pyrolytic graphite sheet TIM.

In an embodiment, a DBM 138 interfaces between bulk semiconductive material of the third die 132 and the third TIM 136. In an embodiment, no DBM 138 is present, and the bulk semiconductive material of the HBM die 132 interfaces at its backside with a carbon-pad TIM 136.

In an embodiment, a first silicon bridge die 140 is embedded in the semiconductor package substrate 112, and the first silicon bridge die 140 is a communications bridge between the processor die 110 and the HBM die 126. By allowing a high-speed interconnect such as the first silicon bridge die 140, the HBM die 126 operates at a speed under conditions of which heat is generated and extracted through the carbon-pad TIM 128 and into the IHS 120.

In an embodiment, a second silicon bridge die 142 is embedded in the semiconductor package substrate 112, and the second silicon bridge die 142 is a communications bridge between the processor die 110 and the third die 132. By allowing a high-speed interconnect such as the second silicon bridge die 142, the third die 132 operates at a speed under conditions of which heat is generated and extracted through the TIM 136 and into the IHS 120.

In an embodiment, the semiconductor package substrate 112 is bonded to a board 158 such as a printed wiring board 158. In an embodiment the board 158 has an integral external shell 160 where the carbon-pad TIM-containing semiconductor device package 100

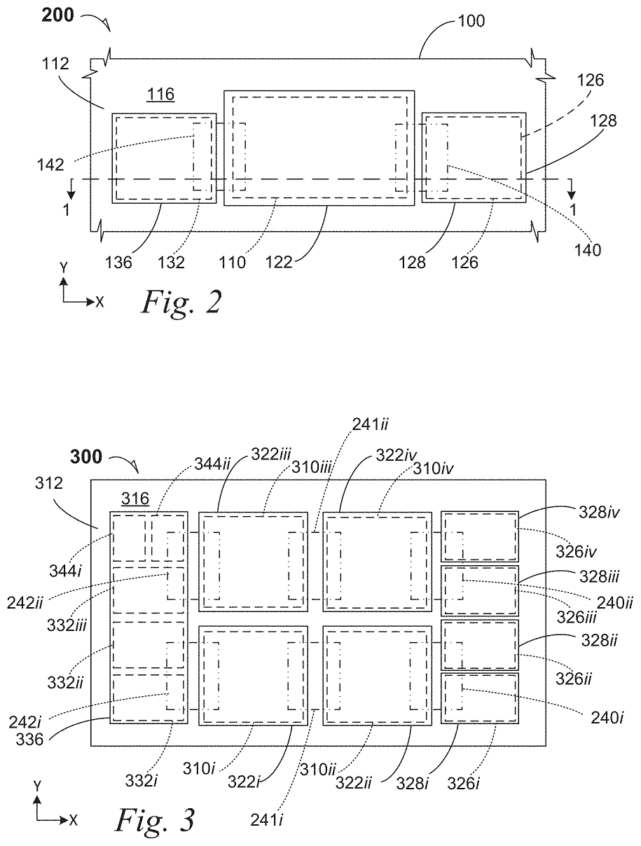

FIG. 2 is a top plan of the semiconductor device package 100 depicted in FIG. 1, where FIG. 1 can be viewed, taken along the section line 1-1 according to several embodiments. The heat sink 120 (see FIG. 1) is removed and the semiconductor package substrate 112 is abbreviated. The die side 116 of the semiconductor package substrate 112, is supporting several structures.

The first semiconductive device 110 is seen in hidden lines as it is below the sTIM 122. The subsequent semiconductive device 126 is seen in hidden lines as it is below the carbon-pad TIM 128. Similarly, the third semiconductive device 132 is seen in hidden lines as it is below the third TIM 136.

The first die 110 is depicted larger than either of the subsequent die 126 and the third die 132, where the first die 110 is a processor die and at least one of the subsequent die 126 and the third die 132 is an ancillary die that receives instructions from the first die 110.

The first EMIB 140 and the second EMIB 142 are also illustrated in ghosted lines, where they are embedded in the semiconductor package substrate 112 and they contact the respective first and subsequent, and first and third chips 110, 126 and 132.

FIG. 3 is a top plan a semiconductor device package 300 according to several embodiments. Similarities with FIG. 2, include a removed heat sink a semiconductor package substrate 312 with a die side 316 supporting several structures.

A first semiconductive device 310 includes a quad layout of disaggregated first semiconductive devices 310i, 310ii, 310iii and 310iv, where these semiconductive devices are an aggregated-die processor. In an embodiment, the first semiconductive devices 310i, 310ii, 310iii and 310iv are an aggregated-die central-processing unit where the several dice are substantially identical. In an embodiment, the first semiconductive devices 310i, 310ii, 310iii and 310iv are an aggregated-die graphics-processing unit where the several dice are substantially identical.

In an embodiment, at least two of the first semiconducting devices. e.g. 310i and 310ii, are an aggregated-die CPU, and at least one of the first semiconductive devices, 310iii is a GPU. Other permutation embodiments include one CPU and three GPUs. Other permutation embodiments include two-each CPUs and GPUs.

In any event, each of the first semiconductive devices are contacted by first sTIMs 322i. 322ii, 322iii and 322iv, respectively. And the several first semiconductive devices are seen in hidden lines as they are below the several sTIMs.

In an embodiment, a strip-array of subsequent semiconductive devices 326 are HBM chips. Each subsequent semiconductive device, e.g. chip 326iii is contacted by a carbon-pad TIM 328iii. In any event, each of the subsequent semiconductive devices are contacted by respective carbon-pad TIMs 328i, 328ii, 328iii and 328iv. Accordingly when deployed below a heat sink, and when useful pressure is applied to the carbon-pad TIMs, thermal resistance for the carbon-pad TIMs is in a range from 0.2 to 0.05 R. ° C. cm2/W.

In an embodiment, at least one structure, e.g. item 326iii is a heat slug that facilitates lateral heat removal from semiconductive devices 326ii and 326iv, as well as a portion of the first semiconductive device 310iv. The remaining several subsequent structures are semiconductive devices in closer relative proximity than that of the several first semiconductive devices 310i, 310ii, 310iii and 310iv.

In an embodiment, a third semiconductive device is a strip-array of third semiconductive devices. e.g. 332i, 332ii and, 332iii. A third TIM 336 is a strip carbon-pad TIM 336 that is attached to at least two of the third semiconductive devices; in this illustrated embodiment, all three of the third semiconductive devices 332i, 332ii and, 3326iii are attached to the strip carbon-pad TIM 336. In an embodiment, the number of third semiconductive devices is two. In an embodiment, the number of third semiconductive devices is three. In an embodiment, the number of third semiconductive devices is four.

In an embodiment, a fourth semiconductive device 344 includes at least one fourth semiconductive device type, 344i and 344ii, that is different from the third semiconductive device types 332 etc. In an embodiment, two, fourth semiconductive devices 344i and 344ii are arrayed next to a processor die, e.g. 310iii, as well as next to a third semiconductive device, e.g. 332iii. And in this embodiment, the strip carbon-pad TIM 336, contacts all third and fourth-type semiconductive devices, 332i, 332ii and 332iii, and 344i and 344ii.

In an embodiment, the strip carbon-pad TIM 336 is applied to the several third- and fourth semiconductive derives, in a tape-automated bonding (TAB) technique.

A first EMIB 240i and a second EMIB 242i are also illustrated in ghosted lines, where they are embedded in the semiconductor package substrate 212 and they contact the respective first and subsequent, and first and third chips. As illustrated, other EMIBs 240ii and 242ii connect first and subsequent and first and third semiconductive devices. Further, central EMIBs 241i and 241ii contact first semiconductive devices.

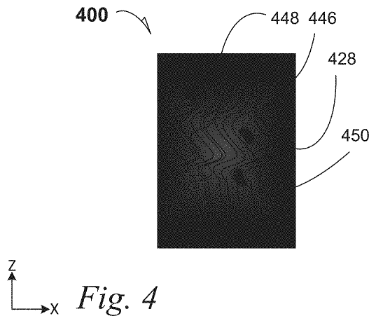

FIG. 4 is a cross-section representation of a carbon-pad thermal interface material 400 according to an embodiment. A carbon-pad TIM 428, under compression, is depicted where carbon-fiber material 446 passes somewhat vertically oriented within a fluoropolymer matrix 448. Incidental lacunae 450 are found within the carbon-pad TIM 428. In an embodiment, the lacunae 450 are incidental to fabricating the carbon-fiber material 446 within a flexible matrix 448 such as a fluoropolymer matrix 448.

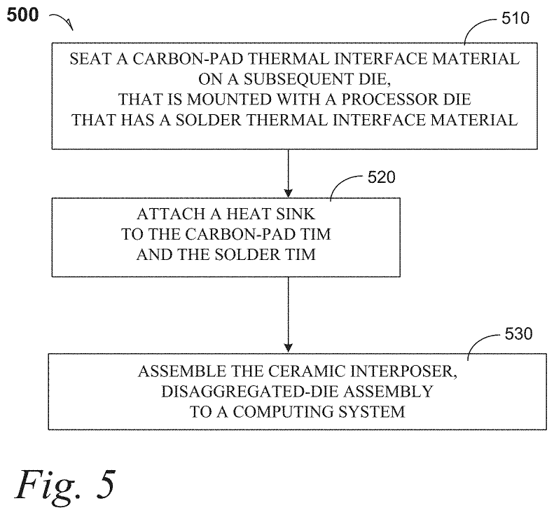

FIG. 5 is a process flow diagram according to several embodiments.

At 510, the process includes seating a carbon-pad thermal interface material on a subsequent die, that is mounted with a processor that has a metallic thermal interface material. In an embodiment, the metallic TIM is an sTIM.

At 520, the process includes attaching a heat sink to the carbon-pad thermal interface material and to the solder thermal interface material.

At 530, the process includes assembling the carbon-pad thermal interface material to a computing system.

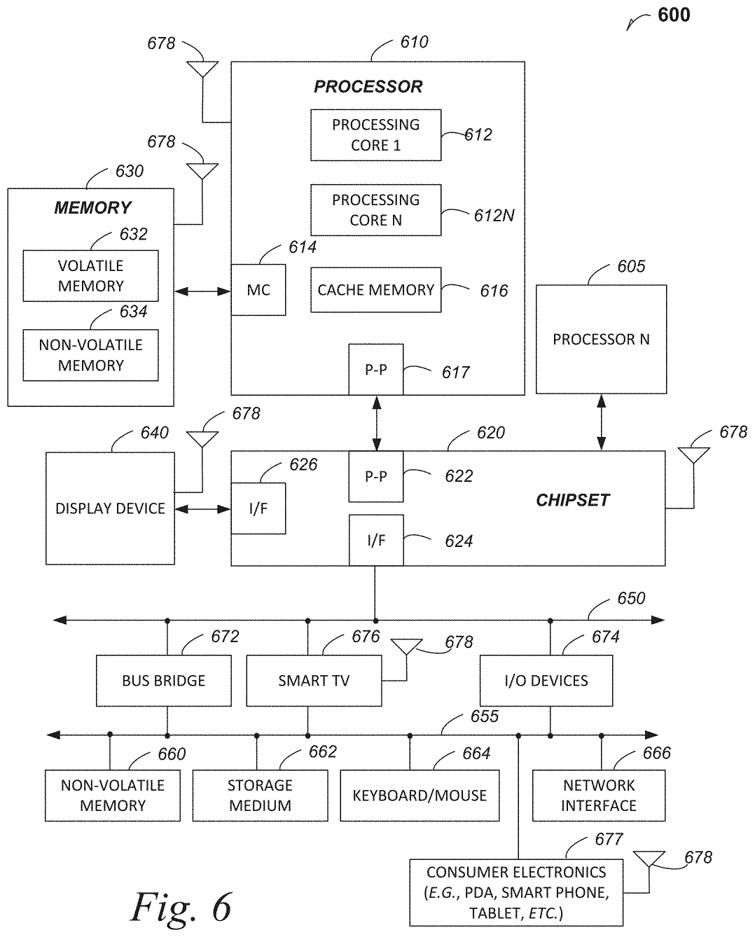

FIG. 6 is included to show an example of a higher-level device application for the disclosed embodiments. The multiple-die with solder and carbon-pad thermal interface materials embodiments may be found in several parts of a computing system. In an embodiment, the multiple-die with solder and carbon-pad thermal interface materials is part of a communications apparatus such as is affixed to a cellular communications tower. In an embodiment, a computing system 600 includes, but is not limited to, a desktop computer. In an embodiment, a system 600 includes, but is not limited to a laptop computer. In an embodiment, a system 600 includes, but is not limited to a netbook. In an embodiment, a system 600 includes, but is not limited to a tablet. In an embodiment, a system 600 includes, but is not limited to a notebook computer. In an embodiment, a system 600 includes, but is not limited to a personal digital assistant (PDA). In an embodiment, a system 600 includes, but is not limited to a server. In an embodiment, a system 600 includes, but is not limited to a workstation. In an embodiment, a system 600 includes, but is not limited to a cellular telephone. In an embodiment, a system 600 includes, but is not limited to a mobile computing device. In an embodiment, a system 600 includes, but is not limited to a smart phone. In an embodiment, a system 600 includes, but is not limited to an internet appliance. Other types of computing devices may be configured with the microelectronic device that includes multiple-die with solder and carbon-pad thermal interface materials embodiments.

In an embodiment, the processor 610 has one or more processing cores 612 and 612N, where 612N represents the Nth processor core inside processor 610 where N is a positive integer. In an embodiment, the electronic device system 600 using an embedded magnetic inductor and EMIB die embodiment that includes multiple processors including 610 and 605, where the processor 605 has logic similar or identical to the logic of the processor 610. In an embodiment, the processing core 612 includes, but is not limited to, pre-fetch logic to fetch instructions, decode logic to decode the instructions, execution logic to execute instructions and the like. In an embodiment, the processor 610 has a cache memory 616 to cache at least one of instructions and data for the embedded magnetic inductor and EMIB die in the system 600. The cache memory 616 may be organized into a hierarchal structure including one or more levels of cache memory.

In an embodiment, the processor 610 includes a memory controller 614, which is operable to perform functions that enable the processor 610 to access and communicate with memory 630 that includes at least one of a volatile memory 632 and a non-volatile memory 634. In an embodiment, the processor 610 is coupled with memory 630 and chipset 620. In an embodiment, the chipset 620 is part of a system-in-package with a multiple-die with solder and carbon-pad thermal interface materials depicted in FIGS. 1, 2 and 3. The processor 610 may also be coupled to a wireless antenna 678 to communicate with any device configured to at least one of transmit and receive wireless signals. In an embodiment, the wireless antenna interface 678 operates in accordance with, but is not limited to, the IEEE 802.11 standard and its related family, Home Plug AV (HPAV), Ultra Wide Band (UWB), Bluetooth, WiMax, or any form of wireless communication protocol.

In an embodiment, the volatile memory 632 includes, but is not limited to, Synchronous Dynamic Random Access Memory (SDRAM). Dynamic Random Access Memory (DRAM), RAMBUS Dynamic Random Access Memory (RDRAM), and/or any other type of random access memory device. The non-volatile memory 634 includes, but is not limited to, flash memory, phase change memory (PCM), read-only memory (ROM), electrically erasable programmable read-only memory (EEPROM), or any other type of non-volatile memory device.

The memory 630 stores information and instructions to be executed by the processor 610. In an embodiment, the memory 630 may also store temporary variables or other intermediate information while the processor 610 is executing instructions. In the illustrated embodiment, the chipset 620 connects with processor 610 via Point-to-Point (PtP or P-P) interfaces 617 and 622. Either of these PtP embodiments may be achieved using a multiple-die with solder and carbon-pad thermal interface materials embodiment as set forth in this disclosure. The chipset 620 enables the processor 610 to connect to other elements in a multiple-die with solder and carbon-pad thermal interface materials embodiment in a system 600. In an embodiment, interfaces 617 and 622 operate in accordance with a PtP communication protocol such as the Intel® QuickPath Interconnect (QPI) or the like. In other embodiments, a different interconnect may be used.

In an embodiment, the chipset 620 is operable to communicate with the processor 610, 605N, the display device 640, and other devices 672, 676, 674, 660, 662, 664, 666, 677, etc. The chipset 620 may also be coupled to a wireless antenna 678 to communicate with any device configured to at least do one of transmit and receive wireless signals.

The chipset 620 connects to the display device 640 via the interface 626. The display 640 may be, for example, a liquid crystal display (LCD), a plasma display, cathode ray tube (CRT) display, or any other form of visual display device. In an embodiment, the processor 610 and the chipset 620 are merged into a multiple-die with solder and carbon-pad thermal interface materials in a computing system. Additionally, the chipset 620 connects to one or more buses 650 and 655 that interconnect various elements 674, 660, 662, 664, and 666. Buses 650 and 655 may be interconnected together via a bus bridge 672 such as at least one multiple-die with solder and carbon-pad thermal interface materials apparatus embodiment. In an embodiment, the chipset 620, via interface 624, couples with a non-volatile memory 660, a mass storage device(s) 662, a keyboard/mouse 664, a network interface 666, smart TV 676, and the consumer electronics 677, etc.

In an embodiment, the mass storage device 662 includes, but is not limited to, a solid state drive, a hard disk drive, a universal serial bus flash memory drive, or any other form of computer data storage medium. In one embodiment, the network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 602.11 standard and its related family, Home Plug AV (HPAV), Ultra Wide Band (UWB), Bluetooth, WiMax. or any form of wireless communication protocol.

While the modules shown in FIG. 6 are depicted as separate blocks within the embedded magnetic inductor and a multiple-die with solder and carbon-pad thermal interface materials in a computing system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into the processor core 612.

Where useful, the computing system 600 may have a broadcasting structure interface such as for affixing the apparatus to a cellular tower.

To illustrate the embedded magnetic inductor and multiple-die with solder and carbon-pad thermal interface materials embodiments and methods disclosed herein, a non-limiting list of examples is provided herein:

Example 1 is a semiconductor device package, comprising: a first semiconductive device on a semiconductor package substrate; a heat sink contacting the first semiconductive device through a metal alloy thermal interface material (TIM); a subsequent semiconductive device on the semiconductor package substrate; a carbon-pad thermal interface material (carbon-pad TIM) contacting the heat sink from a backside of the subsequent semiconductive device, wherein the carbon-pad TIM is configured under compression.

In Example 2, the subject matter of Example 1 optionally includes wherein the metal alloy TIM is a solder TIM (sTIM).

In Example 3, the subject matter of Example 2 optionally includes wherein the first semiconductive device contacts the sTIM at a backside metallurgy, and wherein the subsequent semiconductive device contacts the carbon-pad TIM at bulk semiconductive material at a backside.

In Example 4, the subject matter of any one or more of Examples 1-3 optionally include/Watt.

In Example 5, the subject matter of any one or more of Examples 1-4 optionally include wherein the carbon-pad TIM includes an organic material interstitially mingled with carbon nanotubes.

In Example 6, the subject matter of any one or more of Examples 1-5 optionally include wherein the carbon-pad TIM includes a fluoropolymer material interstitially mingled with carbon nanotubes.

In Example 7, the subject matter of any one or more of Examples 1-6 optionally include wherein the carbon-pad TIM is under compression, between the heat sink and the subsequent semiconductive device on the semiconductor package substrate.

In Example 8, the subject matter of any one or more of Examples 2-7 optionally include a third semiconductive device on the semiconductor package substrate and adjacent the first semiconductive device, wherein the third semiconductive device is contacted by a third thermal interface material, selected from a carbon-pad TIM, an sTIM, an elastomer-pad TIM, a vertically oriented graphitic carbon TIM and a pyrolytic graphite sheet TIM.

In Example 9, the subject matter of any one or more of Examples 1-8 optionally include wherein the first die is a collection of up to four aggregated-die processor dice, wherein the subsequent semiconductive device is a collection of up to four high-bandwidth memory semiconductive devices, and wherein each subsequent die backside is contacted by a carbon-pad TIM.

In Example 10, the subject matter of any one or more of Examples 1-9 optionally include: wherein the first semiconductive is a collection of up to four aggregated-die processor dice; wherein the subsequent semiconductive device is a collection of up to four high-bandwidth memory semiconductive devices; wherein each subsequent die backside is contacted by a carbon-pad TIM, further including: wherein a third die is a collection of up to four semiconductive devices on the substrate die side; and wherein a third TIM is a carbon-pad TIM in a strip form factor that contacts each of the third semiconductive dice at each third-die on a backside surface.

In Example 11, the subject matter of any one or more of Examples 1-10 optionally include: wherein the first semiconductive device is a collection of up to four aggregated-die processor dice; wherein the subsequent semiconductive device is a collection of up to four high-bandwidth memory semiconductive devices; wherein each subsequent semiconductive device backside is contacted by a carbon-pad TIM, further including: wherein a third semiconductive device is a collection of up to four semiconductive devices on the semiconductor package die side; wherein a third TIM is a carbon-pad TIM in a strip form factor that contacts each of the third semiconductive devices at each third-die on a backside surface; and at least one fourth semiconductive device adjacent one of the at least one third semiconductive devices, and wherein the carbon-pad TIM in strip form factor also contacts the at least one fourth semiconductive device on the fourth-semiconductive device on a backside surface.

In Example 12, the subject matter of any one or more of Examples 1-11 optionally include wherein the first semiconductive device is a collection of up to four aggregated-die processor dice, wherein at least two of the aggregated-die processor dice are central-processing unit semiconductive devices, wherein at least one of the aggregated-die processor dice is a graphics-processing unit semiconductive device, and wherein each subsequent device backside is contacted by a carbon-pad TIM at each subsequent-semiconductive device backside surface.

In Example 13, the subject matter of any one or more of Examples 1-12 optionally include the carbon-pad TIM provides a thermal resistance between 0.05 and 0.2° C. cm2/Watt. and wherein the carbon-pad TIM has a bond-line thickness in a range between 250 and 450 micrometer.

In Example 14, the subject matter of any one or more of Examples 1-13 optionally include wherein the first semiconductive device and the subsequent semiconductive device communicate through an embedded multi-die interconnect bridge that is embedded in the semiconductor package substrate.

In Example 15, the subject matter of any one or more of Examples 1-14 optionally include a third semiconductive device on the semiconductor package substrate and adjacent the first semiconductive device, wherein the third semiconductive device is contacted by a carbon-pad TIM; wherein the first semiconductive device and the subsequent semiconductive device communicate through an embedded multi-die interconnect bridge that is embedded in the semiconductor package substrate; and wherein the first semiconductive device and the third semiconductive device communicate through an embedded multi-die interconnect bridge that is embedded in the semiconductor package substrate.

Example 16 is a computing system, comprising: a first semiconductive device on a semiconductor package substrate, wherein the first semiconductive device is a processor die; a heat sink contacting the first semiconductive device at a die backside metallurgy and through a solder thermal interface material (sTIM); a subsequent semiconductive device on the semiconductor package substrate, wherein the subsequent semiconductive device is a high-bandwidth memory die; a carbon-pad thermal interface material (carbon-pad TIM) contacting the high-bandwidth memory die at a backside at bulk semiconductive material, wherein the carbon-pad TIM also contacts the heat sink, wherein the carbon-pad TIM is configured under compression from the heat sink; a third semiconductive device on the semiconductor package substrate, wherein the third semiconductive device is contacted by a carbon-pad TIM at a third-die at a backside at bulk semiconductive material; and wherein the first, subsequent and third semiconductive devices are part of a chipset.

In Example 17, the subject matter of Example 16 optionally includes wherein the first semiconductive device is a collection of up to four aggregated-die processor dice; wherein at least one of the up to four aggregated-die processor dice is a central-processing unit, wherein at least one of the up to four aggregated-die processor dice is a graphics-processing unit; wherein the subsequent semiconductive device is a collection of up to four high-bandwidth memory semiconductive devices; wherein each subsequent device backside is contacted by a carbon-pad TIM; and wherein the third semiconductive device is a collection of up to four semiconductive devices.

In Example 18, the subject matter of any one or more of Examples 16-17 optionally include wherein the first semiconductive device is a collection of up to four aggregated-die processor dice; wherein at least one of the up to four aggregated-die processor dice is a central-processing unit, wherein at least one of the up to four aggregated-die processor dice is a graphics-processing unit; wherein the subsequent semiconductive device is a collection of up to four high-bandwidth memory semiconductive devices; wherein each subsequent semiconductive device backside is contacted by a carbon-pad TIM; and wherein the third semiconductive device is a collection of up to four semiconductive devices, and wherein a strip form-factor carbon-pad TIM contacts each of the third semiconductive devices at bulk semiconductive material on each die backside.

In Example 19, the subject matter of any one or more of Examples 16-18 optionally include wherein the carbon-pad TIM includes a fluoropolymer material interstitially mingled with carbon nanotubes.

In Example 20, the subject matter of any one or more of Examples 16-19 optionally include the carbon-pad TIM further including a thermal resistance between 0.05 and 0.2° C. cm²/Watt; a bond-line thickness in a range between 250 and 450 micrometer; and a fluoropolymer material interstitially mingled with carbon nanotubes.

Example 21 is a process of assembling a semiconductor device package, comprising: seating a processor semiconductive device on a semiconductor package substrate; locating a solder thermal interface material on the processor semiconductive device on a die backside metallurgy; seating a high-bandwidth memory die on the semiconductor package substrate; and locating a carbon-pad thermal interface material on the high-bandwidth memory die on the die backside surface at bulk semiconductive material.

In Example 22, the subject matter of Example 21 optionally includes wherein seating the processor semiconductive device includes seating a disaggregated-die collection of up to four dice, wherein at least one of the processor semiconductive devices is a central-processing unit; and wherein the high-bandwidth memory die is a disaggregated-die collection of up to four dice, and wherein seating the high-bandwidth memory die includes putting the high-bandwidth memory die under compression through the carbon-pad thermal interface material from a heat sink.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electrical device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the disclosed embodiments should be determined with reference to the appended claims, along with the full scope of equivalents to which such claims are entitled.

1. A semiconductor device package, comprising:
a first semiconductive device on a semiconductor package substrate;
a heat sink contacting the first semiconductive device through a metal alloy thermal interface material (TIM);
a subsequent semiconductive device on the semiconductor package substrate;
a carbon-pad thermal interface material (carbon-pad TIM) contacting the heat sink from a backside of the subsequent semiconductive device, wherein the carbon-pad TIM is configured under compression.

2. The semiconductor device package of claim 1, wherein the metal alloy TIM is a solder TIM (sTIM).

3. The semiconductor device package of claim 2, wherein the first semiconductive device contacts the sTIM at a backside metallurgy, and wherein the subsequent semiconductive device contacts the carbon-pad TIM at bulk semiconductive material at a backside.

4. The semiconductor device package of claim 1, wherein the carbon-pad TIM is configured to sustain a thermal resistance in a range from 0.04 to 0.25° C. cm²/Watt.

5. The semiconductor device package of claim 1, wherein the carbon-pad TIM includes an organic material interstitially mingled with carbon nanotubes.

6. The semiconductor device package of claim 1, wherein the carbon-pad TIM includes a fluoropolymer material interstitially mingled with carbon nanotubes.

7. The semiconductor device package of claim 1, wherein the carbon-pad TIM is under compression, between the heat sink and the subsequent semiconductive device on the semiconductor package substrate.

8. The semiconductor device package of claim 2, further including a third semiconductive device on the semiconductor package substrate and adjacent the first semiconductive device, wherein the third semiconductive device is contacted by a third thermal interface material, selected from a carbon-pad TIM, an sTIM, an elastomer-pad TIM, a vertically oriented graphitic carbon TIM and a pyrolytic graphite sheet TIM.

9. The semiconductor device package of claim 1, wherein the first die is a collection of up to four aggregated-die processor dice, wherein the subsequent semiconductive device is a collection of up to four high-bandwidth memory semiconductive devices, and wherein each subsequent die backside is contacted by a carbon-pad TIM.

10. The semiconductor device package of claim 1:
wherein the first semiconductive is a collection of up to four aggregated-die processor dice;
wherein the subsequent semiconductive device is a collection of up to four high-bandwidth memory semiconductive devices;
wherein each subsequent die backside is contacted by a carbon-pad TIM, further including:
wherein a third die is a collection of up to four semiconductive devices on the substrate die side; and
wherein a third TIM is a carbon-pad TIM in a strip form factor that contacts each of the third semiconductive dice at each third-die on a backside surface.

11. The semiconductor device package of claim 1:
wherein the first semiconductive device is a collection of up to four aggregated-die processor dice;
wherein the subsequent semiconductive device is a collection of up to four high-bandwidth memory semiconductive devices;
wherein each subsequent semiconductive device backside is contacted by a carbon-pad TIM, further including:
wherein a third semiconductive device is a collection of up to four semiconductive devices on the semiconductor package die side;
wherein a third TIM is a carbon-pad TIM in a strip form factor that contacts each of the third semiconductive devices at each third-die on a backside surface; and
at least one fourth semiconductive device adjacent one of the at least one third semiconductive devices, and wherein the carbon-pad TIM in strip form factor also contacts the at least one fourth semiconductive device on the fourth-semiconductive device on a backside surface.

12. The semiconductor device package of claim 1, wherein the first semiconductive device is a collection of up to four aggregated-die processor dice, wherein at least two of the aggregated-die processor dice are central-processing unit semiconductive devices, wherein at least one of the aggregated-die processor dice is a graphics-processing unit semiconductive device, and wherein each subsequent device backside is contacted by a carbon-pad TIM at each subsequent-semiconductive device backside surface.

13. The semiconductor device package of claim 1, wherein the carbon-pad TIM provides a thermal resistance between 0.05 and 0.2° C. cm²/Watt, and wherein the carbon-pad TIM has a bond-line thickness in a range between 250 and 450 micrometer.

14. The semiconductor device package of claim 1, wherein the first semiconductive device and the subsequent semiconductive device communicate through an embedded multi-die interconnect bridge that is embedded in the semiconductor package substrate.

15. The semiconductor device package of claim 1, further including:
a third semiconductive device on the semiconductor package substrate and adjacent the first semiconductive device, wherein the third semiconductive device is contacted by a carbon-pad TIM;
wherein the first semiconductive device and the subsequent semiconductive device communicate through an embedded multi-die interconnect bridge that is embedded in the semiconductor package substrate; and
wherein the first semiconductive device and the third semiconductive device communicate through an embedded multi-die interconnect bridge that is embedded in the semiconductor package substrate.

16. A computing system, comprising:
a first semiconductive device on a semiconductor package substrate, wherein the first semiconductive device is a processor die;
a heat sink contacting the first semiconductive device at a die backside metallurgy and through a solder thermal interface material (sTIM);
a subsequent semiconductive device on the semiconductor package substrate, wherein the subsequent semiconductive device is a high-bandwidth memory die;
a carbon-pad thermal interface material (carbon-pad TIM) contacting the high-bandwidth memory die at a backside at bulk semiconductive material, wherein the carbon-pad TIM also contacts the heat sink, wherein the carbon-pad TIM is configured under compression from the heat sink;
a third semiconductive device on the semiconductor package substrate, wherein the third semiconductive device is contacted by a carbon-pad TIM at a third-die at a backside at bulk semiconductive material; and
wherein the first, subsequent and third semiconductive devices are part of a chipset.

17. The computing system of claim 16, wherein the first semiconductive device is a collection of up to four aggregated-die processor dice;
wherein at least one of the up to four aggregated-die processor dice is a central-processing unit, wherein at least one of the up to four aggregated-die processor dice is a graphics-processing unit;
wherein the subsequent semiconductive device is a collection of up to four high-bandwidth memory semiconductive devices;
wherein each subsequent device backside is contacted by a carbon-pad TIM; and
wherein the third semiconductive device is a collection of up to four semiconductive devices.

18. The computing system of claim 16, wherein the first semiconductive device is a collection of up to four aggregated-die processor dice;
wherein at least one of the up to four aggregated-die processor dice is a central-processing unit, wherein at least one of the up to four aggregated-die processor dice is a graphics-processing unit;
wherein the subsequent semiconductive device is a collection of up to four high-bandwidth memory semiconductive devices;
wherein each subsequent semiconductive device backside is contacted by a carbon-pad TIM; and
wherein the third semiconductive device is a collection of up to four semiconductive devices,
and wherein a strip form-factor carbon-pad TIM contacts each of the third semiconductive devices at bulk semiconductive material on each die backside.

19. The computing system of claim 16, wherein the carbon-pad TIM includes a fluoropolymer material interstitially mingled with carbon nanotubes.

20. The computing system of claim 16, the carbon-pad TIM further including:
a thermal resistance between 0.05 and 0.2° C. cm²/Watt;
a bond-line thickness in a range between 250 and 450 micrometer; and
a fluoropolymer material interstitially mingled with carbon nanotubes.

21-22. (canceled)
